(19) United States
(12) Patent Application Publication
(10) Pub. No.: US 2010/0051322 A1
(43) Pub. Date: Mar. 4, 2010

(54) PRINTED CIRCUIT BOARD AND MANUFACTURING METHOD

(75) Inventors: Woon-Chun KIM, Suwon-si (KR); Soon-Gyu YIM, Seongnam-si (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/367,910

(22) Filed: Feb. 9, 2009

(30) Foreign Application Priority Data
Sep. 3, 2008 (KR) 10-2008-0086888

(51) Int. Cl. H05K 1/00; B32B 38/00; C25D 7/00; C23F 1/00

(52) U.S. Cl. 174/250; 156/280; 156/153; 156/150; 216/13

(57) ABSTRACT

Disclosed are a printed circuit board and a method for manufacturing the same. The method, which includes forming a relievo pattern corresponding to a first circuit pattern on a thin-film insulating layer stacked on a carrier; stacking and compressing the carrier with the insulator such that one surface of the carrier on which the relievo pattern is formed faces the insulator; transcribing the thin-film insulating layer and the relievo pattern in the insulator; exposing a part of the relievo pattern by opening a part of the thin-film insulating layer; and forming a second circuit pattern by selectively depositing a conductive metal on the thin-film insulating layer, can manufacture a printed circuit board having high-density circuit patterns by forming a double layer circuit patterns, one circuit pattern buried in the insulator and the other circuit pattern formed on the outer layer, without stacking the insulator for forming a multi-layered printed circuit board.

### CROSS-REFERENCE TO RELATED APPLICATIONS

This application claims the benefit of Korean Patent Application No. 10-2008-0086888, filed with the Korean Intellectual Property Office on Sep. 3, 2008, the disclosure of which is incorporated herein by reference in its entirety.

### BACKGROUND

1. Technical Field

The present invention relates to a printed circuit board and a method for manufacturing the same.

2. Description of the Related Art

As electronic products become increasingly smaller and thinner, printed circuit boards are also undergoing a change toward smaller size, finer patterns, and higher density. Accordingly, along with changes in the raw material for forming finer patterns, improving reliability and increasing design density, the layer composition of the circuit is integrated.

In response to the increased complexity of the circuit and the demands for high-density, finer pattern circuit, various forms of multi-layered circuit boards have been proposed. However, conventional manufacturing methods, including the photolithography method and the build-up method, involve complicated processes and require a minimum pitch between adjacent circuits due to, for example, ion migration, so that there have been limitations in forming fine-line circuit patterns.

In addition, the multi-layered circuit board has been too thick to implement a thin board, and the circuit is exposed over the insulating layer, causing an undercut where the circuit and the board are attached and making the circuit peeled off from the board.

### SUMMARY

The present invention provides a printed circuit board and a method for manufacturing the same, in which a double layer circuit patterns, one circuit pattern buried in the insulator and the other circuit pattern formed on the outer layer, are formed without stacking the insulator for forming the multi-layered printed circuit board, to offer high-density circuit patterns.

The present invention also provides a printed circuit board and a method for manufacturing the same, in which a thin-film insulating layer is formed between the circuit pattern buried in the insulator and the circuit pattern formed on the outer layer, to reduce the pitch between adjacent circuits and thus form high density fine-line circuit patterns.

An aspect of the invention features a method for manufacturing a printed circuit board, including forming a relievo pattern corresponding to a first circuit pattern on a thin-film insulating layer stacked on a carrier; stacking and compressing the carrier with an insulator such that one surface of the carrier on which the relievo pattern is formed faces the insulator; transcribing the thin-film insulating layer and the relievo pattern in the insulator by removing the carrier; exposing a part of the relievo pattern by opening a part of the thin-film insulating layer; and forming a second circuit pattern by selectively depositing a conductive metal on the thin-film insulating layer.

Roughness can be formed on the thin-film insulating layer by a desmear process. In this case, prior to the forming of the relievo pattern, desmearing the thin-film insulating layer of the carrier can be further included.

The forming of the relievo pattern can include forming a seed layer on the thin-film insulating layer; forming a plating resist on the seed layer to correspond to the relievo pattern; performing electroplating by using the seed layer as an electrode; peeling off the plating resist; and removing the exposed seed layer.

The forming of the second circuit pattern can include forming a seed layer on the thin-film insulating layer; forming a plating resist on the seed layer to correspond to the second circuit pattern; performing electroplating by using the seed layer as an electrode; peeling off the plating resist; and removing the exposed seed layer.

The carrier can be a metal plate, and the transcribing can be performed by etching the metal plate.

The forming of the relievo pattern can include forming a relievo pattern on each of the thin-film insulating layers of two carriers; the compressing comprises stacking and compressing the two carriers with the insulator such that one surface of each of the two carriers, on which the relievo pattern is formed, faces either surface of the insulator; and the transcribing comprises removing the two carriers.

The forming of the relievo pattern on each of the thin-film insulating layers can include forming a relievo pattern on the thin-film insulating layer of each of the two carriers, of which the other surface is adhered to either surface of a foam adhesive layer; and separating the two carriers from each other by foaming the foam adhesive layer.

The forming of the relievo pattern can be performed by forming a conductive layer on the thin-film insulating layer and selectively removing the conductive layer.

Another aspect of the invention features a printed circuit board including an insulator; a first circuit pattern being buried on one surface of the insulator; a thin-film insulating layer being formed on one surface of the insulator; and a second circuit pattern being formed on the thin-film insulating layer.

Roughness can be formed on the thin-film layer by a desmear process.

A part of the second circuit pattern can be formed to overlap with a part of the first circuit pattern by removing a part of the thin-film insulating layer to expose a part of the first circuit pattern.

### BRIEF DESCRIPTION OF THE DRAWINGS

FIG. 1 is a flowchart showing a method for manufacturing a printed circuit board in accordance with an embodiment of the present invention;

FIG. 2 through FIG. 17 show how a printed circuit board is manufactured in accordance with an embodiment of the present invention;

FIG. 18 through FIG. 21 show some of a method for manufacturing a printed circuit board in accordance with another embodiment of the present invention;

FIG. 22 is a sectional view showing a printed circuit board in accordance with an embodiment of the present invention.

### DETAIL DESCRIPTION

Since there can be a variety of permutations and embodiments of the present invention, certain embodiments will be illustrated and described with reference to the accompanying drawings. This, however, is by no means to restrict the present invention to certain embodiments, and shall be construed as including all permutations, equivalents and substitutes covered by the spirit and scope of the present invention. Throughout the drawings, similar elements are given similar reference numerals. Throughout the description of the present invention, when describing a certain technology is determined to evade the point of the present invention, the pertinent detailed description will be omitted.

Terms such as “first” and “second” can be used in describing various elements, but the above elements shall not be restricted to the above terms. The above terms are used only to distinguish one element from the other.

The terms used in the description are intended to describe certain embodiments only, and shall by no means restrict the present invention. Unless clearly used otherwise, expressions in the singular number include a plural meaning. In the present description, an expression such as “comprising” or “consisting of” is intended to designate a characteristic, a number, a step, an operation, an element, a part or combinations thereof, and shall not be construed to preclude any presence or possibility of one or more other characteristics, numbers, steps, operations, elements, parts or combinations thereof.

A printed circuit board and a method for manufacturing the printed circuit according to an embodiment of the present invention will be described below in more detail with reference to the accompanying drawings, in which those components are rendered the same reference numerals that are same or are in correspondence, regardless of the figure number, and redundant explanations will be omitted.

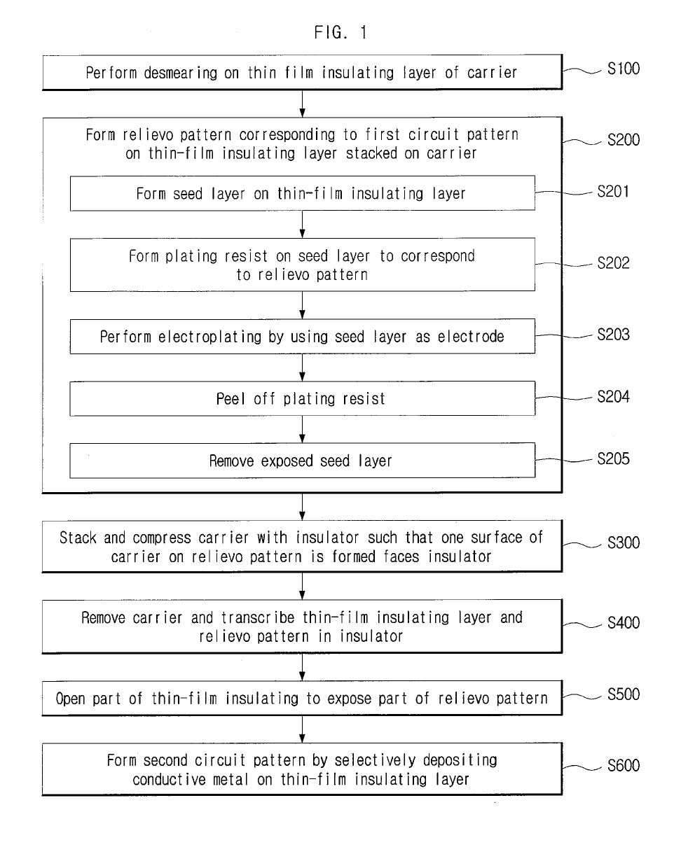

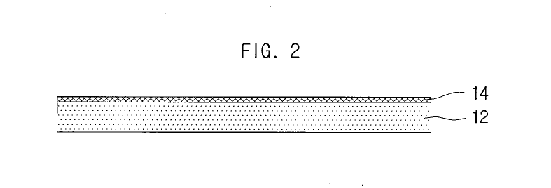

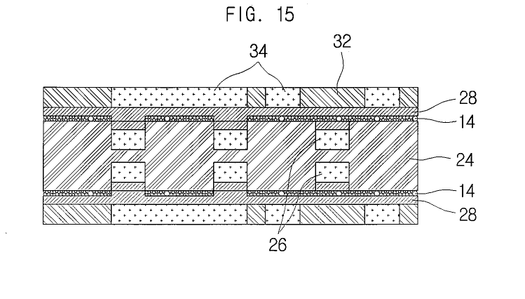

FIG. 1 is a flowchart showing a method for manufacturing a printed circuit board in accordance with an embodiment of the present invention, and FIG. 2 through FIG. 17 show how a printed circuit board is manufactured in accordance with an embodiment of the present invention. In FIG. 2 through FIG. 17 are shown a carrier 12, a thin-film insulating layer 14, seed layers 16 and 28, plating resists 18 and 30, plating 20 and 34, a relievo pattern 22, an insulator 24, a window 25, a first circuit pattern 26, and a second circuit pattern 36.

In accordance with an embodiment of the present invention, the method for manufacturing the printed circuit board, which includes forming the relievo pattern 22 corresponding to the first circuit pattern 26 on the thin-film insulating layer 14 stacked on the carrier 12; stacking and compressing the carrier 12 with the insulator 24 such that one surface of the carrier 12 on which the relievo pattern 22 is formed faces the insulator 24; removing the carrier and transcribing the thin-film insulating layer 14 and the relievo pattern 22 in the insulator 24; opening a part of the thin-film insulating layer 14 to expose a part of the relievo pattern 22; and selectively depositing a conductive metal to form the second circuit pattern 36, can manufacture a circuit board having high-density circuit patterns by forming a double layer circuit patterns, one circuit pattern buried in the insulator and the other circuit pattern formed on the outer layer without stacking the insulator for forming the multi-layered printed circuit board.

The method can also form high density fine-line circuit patterns by forming the thin-film insulating layer between the circuit pattern buried in the insulator and the circuit pattern formed on the outer layer, to reduce the pitch between adjacent circuits.

Hereinafter, the method for manufacturing the printed circuit board according to this embodiment of the present invention will be described. Firstly, as shown in FIG. 2 through FIG. 8, an operation represented by S100 can perform a desmear process for the thin-film insulating layer 14 stacked on the carrier 12. Then, an operation represented by S200 can form the relievo pattern 22 corresponding to the first circuit pattern 26 on the thin-film insulating layer 14 stacked on the carrier 12.

In the present invention, the thin-film insulating layer 14 can be an insulating layer having a thickness that is thinner than that of the insulator stacked to manufacture a multi-layered printed circuit board.

In accordance with this embodiment of the present invention, the thin-film insulating layer 14 can be stacked on the carrier 12, and the thin-film insulating layer 14 can be formed with a roughness by the desmear process.

The desmear process can be typically performed to remove a smear remaining on an inner wall of a via hole when the via hole of a board is processed. In this embodiment of the present invention, however, a roughness can be formed on the thin-film insulating layer 14 by stacking an epoxy resin or a polyamide imide having a polymer, capable of the chemical roughing, as the thin-film insulating layer 14 on the carrier 12 and performing the desmear process.

A filler can be removed in an inside of the thin-film insulating layer 14 by performing the swelling of the thin-film insulating layer 14 with an oxidizer, such as permanganate, non-chromate, or hydrogen peroxide, through the desmear process in order to allow the thin-film insulating layer 14 to be formed with a roughness.

In this case, since the thin-film insulating layer 14 is thinly stacked on the carrier 12, the roughness can be also formed on a surface of the thin-film insulating layer, which is in contact with the carrier 12 by the desmear process. This roughness of the thin-film insulating layer 140 can improve the bond strength of a circuit pattern and the relievo pattern 22, being formed on the thin-film insulating layer 14.

This embodiment suggests the method of performing the desmear process for the thin-film insulating layer 14. However, if the bond strength of the relievo pattern 22 is not a problem, it can be possible to form the relievo pattern 22 on the thin-film insulating layer 14 without performing the desmear process.

The relievo pattern 22 corresponding to the first circuit pattern 26 can be formed on the thin-film insulating layer 14 stacked on the carrier 12 by using various ways, which are evident to any person of ordinary skill in the art, such as a subtractive method or an additive method. Here, the subtractive method can form the relievo pattern 22 by forming a conductive layer on the thin-film insulating layer 14 and selectively removing the conductive layer. The additive method can form the relievo pattern 22 by selectively depositing a conductive material on the thin-film insulating layer 14 through a sputtering or plating process. Thereafter, the relievo pattern 22 can be buried in the insulator 24 to form the first circuit pattern 26.

This embodiment of the present invention suggests the method of forming the relievo pattern 22 by selectively depositing a conductive material through the plating process.

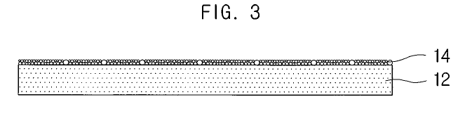

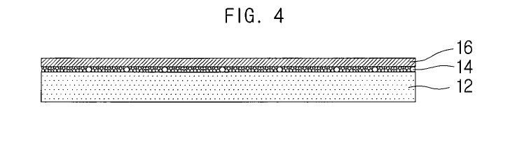

Firstly, an operation represented by S201 can perform the desmear process for the thin-film insulating layer 14 of the carrier 12 to form a roughness as shown in FIG. 2 and FIG. 3 and form the seed layer 16 on the thin-film insulating layer 14 as shown in FIG. 4. The seed layer 16 can be formed by an electroless plating or sputtering process. In accordance with this embodiment of the present invention, the electroless plating process is performed to form the seed layer 16 on the thin-film insulating layer 14.

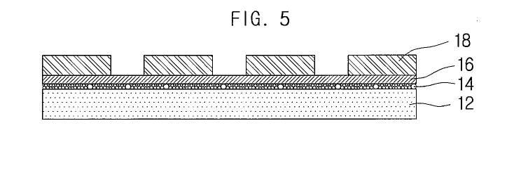

Next, an operation represented by S202 can form the plating resist in the seed layer 16 to correspond to the relievo pattern 22 as shown in FIG. 5. In particular, a photosensitive material such as a dry film can be stacked on the seed layer 16, and a photomask can be manufactured corresponding to the relievo pattern 22. Then, the photomask can be stacked on the seed layer 16 to which the photosensitive material is applied before being exposed to ultraviolet rays. Thereafter, an intaglio pattern can be formed corresponding to the relievo pattern 22 on the seed layer 16 by developing an uncured part of the photosensitive material with a developer.

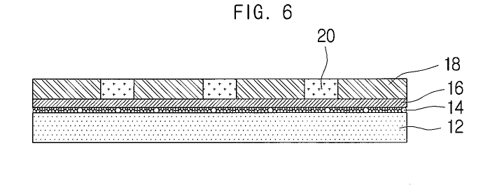

Next, an operation represented by S203 can perform the electroplating by using the seed layer 16 as an electrode as shown in FIG. 6 to fill the plating 20 in the intaglio pattern, which is formed by the plating resist 18,

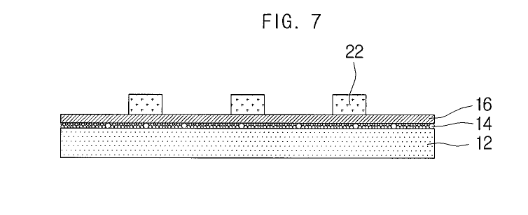

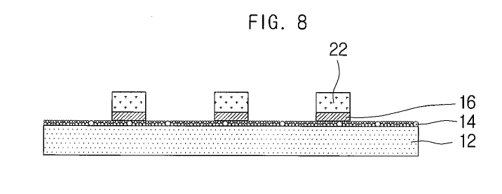

Then, as shown in FIG. 7 and FIG. 8, an operation represented by S204 can peel off the plating resist 18 and an operation represented by S205 can remove the exposed seed layer 16, thereby forming the relievo pattern 22 corresponding to the first circuit pattern 26 on the thin-film insulating layer 14 of the carrier 12.

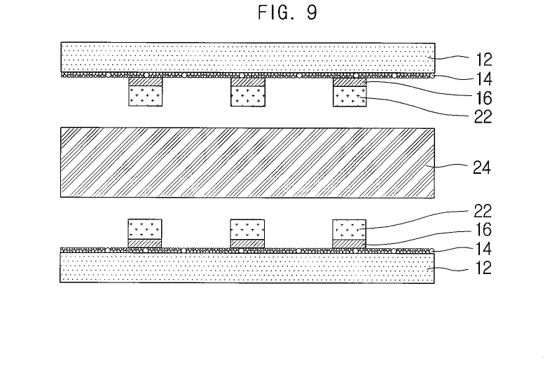

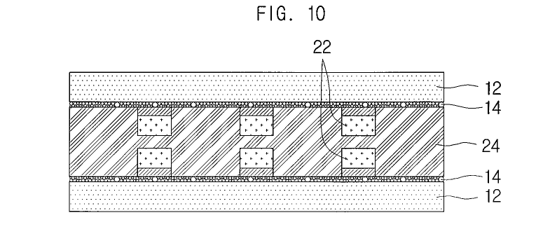

Next, an operation represented by S300 can stack and compress the carrier 12 with the insulator 24 such that one surface of the carrier 12 on which the relievo pattern 22 is formed faces the insulator 24 as shown in FIG. 9 and FIG. 10.

This embodiment of the present invention suggests a method of stacking two carriers 12 on either surfaces of the insulators 24 and compressing the two carriers to form the first circuit pattern 26 on either surfaces of the insulator 24. In particular, the relievo pattern 22 can be formed on each of the thin-film insulting layers 14 of two carriers 12. The two carriers 12 can be stacked and compressed such that one surface of each of the two carriers 12, on which the relievo pattern 22 is formed faces the insulator 24, thereby allowing the relievo patterns 22 to be pressed in the insulator 24.

The insulator 24 can include at least one of a thermoplastic resin and a glass epoxy resin. When the relievo pattern 22 is buried in the insulator 24, the insulator 24 remains soft. In particular, the insulator 24 can be made soft by heating the thermoplastic resin and the glass epoxy resin at a temperature that is equal to or greater than a corresponding softening point before the relievo pattern 22 embossed on the thin-film insulating layer 14 of the carrier 12 is compressed in the softened insulator 24. On the other hand, it can be possible to use as the insulator 24 a prepreg that is half-cured by permeating the thermoplastic resin into glass fiber.

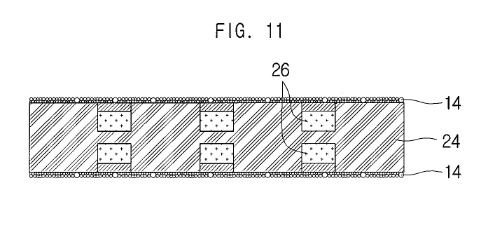

Next, an operation represented by S400 can remove the carrier 12 and transcribe the thin-film insulating layer 14 and the relievo pattern 22 in the insulator 24 as shown in FIG. 11. When the carrier 12 is removed, in case that the carrier 12 is a metal plate, the metal plate is etched. In case that the carrier 12 is a resin film that bonds with the thin-film insulating layer 14 by a foam adhesive, the foam adhesive is foamed by increasing temperature.

The relievo pattern 22 can be compressed in the insulator 24 and be transcribed in the insulator 24 by the removing of the carrier 12, thereby forming the first circuit pattern 26 in the form of being buried in the insulator 24. The first circuit pattern 26 formed in the form of being buried in the insulator 24 can improve the bond strength because of its broad contact area with the insulator 24.

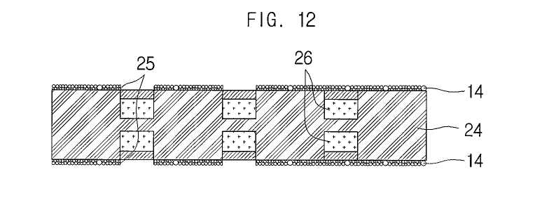

Next, an operation represented by S500 can open a part of the thin-film insulating layer 14 to expose a part of the relievo pattern 22 as shown in FIG. 12. The window 25 can be formed by opening a part of the thin-film insulating layer 14 to expose a part of the relievo pattern 22. The reason of exposing a part of the relievo pattern 22 is to be electrically connected to the second circuit pattern 36 being formed above the thin-film insulating layer 14.

When a thick insulator is stacked to manufacture a multi-layered printed circuit board in accordance with the conventional art, it is necessary to form a via hole for electrical connection between circuits and to fill the plating in the via hole in order to form a via. In accordance with the present invention, however, it can be possible to omit the filling process by using a thin-film insulating layer.

A part of the thin-film insulating layer 14 can be opened by various ways, which are evident to any person of ordinary skill in the art, for example, by selectively performing the desmear process for the thin-film insulting layer 14 or by using a laser drill.

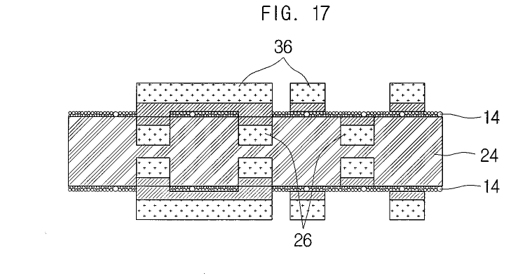

Next, an operation represented by S600 can selectively deposit a conductive metal on the thin-film insulating layer 14 to form the second circuit pattern 36 as shown in FIG. 17.

The second circuit pattern 36 can be formed on the thin-film insulating layer 14 stacked on the insulator 24 by using various ways, which are evident to any person of ordinary skill in the art, such as a subtractive method or an additive method. Here, the subtractive method can form the relievo pattern 22 by forming a conductive layer on the thin-film insulating layer 14 and selectively removing the conductive layer. The additive method can form the relievo pattern 22 by selectively depositing a conductive material in the thin-film insulating layer 14 through a sputtering or plating process.

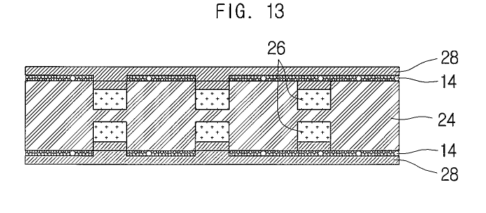

This embodiment of the present invention suggests a method of selectively depositing a conductive material by the plating to form the second circuit pattern 36 as shown in FIG. 13 through FIG. 17.

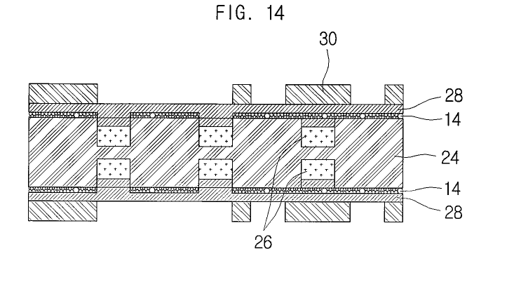

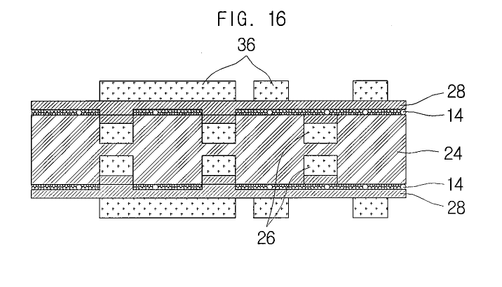

In particular, the plating 34 can be filled in an intaglio pattern, which is formed by the plating resist 30, by forming the seed layer 28 on the thin-film insulating layer 14 as shown in FIG. 13, forming the plating resist 30 on the seed layer 28 to correspond to the seed layer 28 as shown in FIG. 14, and performing the electroplating by use of the seed layer 28 as an electrode. Then, the plating resist 30 can be peeled off as shown in FIG. 16 and the exposed seed layer 28 can be removed as shown in FIG. 17, thereby forming the second circuit pattern 36 on the thin-film insulating layer 14.

In this case, the window 25 exposing a part of the first circuit pattern 26 in the process of forming the seed layer 28 and the electroplating process is filled with the plating by the thin-film insulating 14, thereby making the electrical connection between the first circuit pattern 26 and the second circuit pattern 36. Accordingly, it can be possible to omit the process of forming a via.

In the case of the thin-film insulating layer 14 being formed with the second circuit pattern 36, roughness can be formed on one surface of the thin-film insulating layer 14, which is in contact with the carrier 12, by the previous desmear process. Accordingly, when the thin-film insulating layer 14 is transcribed in the insulator 24, roughness can be also formed on a surface in which the thin-film insulating layer 14 is transcribed. Thus, the roughness of the thin-film insulating layer 14 can improve the bond strength of the second circuit pattern 36.

With the aforementioned method, it can be possible to manufacture a printed circuit board having high-density circuit patterns by forming a double layer circuit patterns, one circuit pattern buried in the insulator and the other circuit pattern formed on the outer layer, without stacking the insulator for forming a multi-layered printed circuit board.

Moreover, since the multi-layered printed circuit board can be formed without the increase of insulators, thereby reducing the overall thickness and material costs.

In addition, the desmear process can form roughness on the thin-film insulating layer, thereby improving the bond strength of circuit patterns.

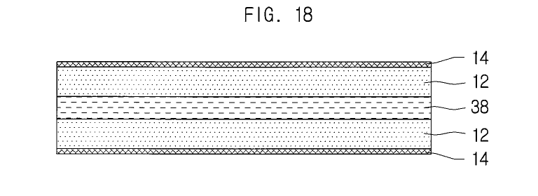

FIG. 18 through FIG. 21 show some of a method for manufacturing a printed circuit board in accordance with another embodiment of the present invention. In FIG. 18 through FIG. 21 are shown the carrier 12, the thin-film insulating layer 14, the relievo pattern 22, and a foam adhesive layer 38.

In accordance with this embodiment of the present invention, the method for manufacturing a printed circuit board, which is to simultaneously form the relievo pattern 22 on each of the thin-film insulating layers 14 of two carriers 12, can include forming the relievo pattern 22 on the thin-film insulating layers 14 of the two carriers 12, of which the other surface is adhered to either surfaces of the foam adhesive layer 38 and foaming the foam adhesive layer 38 to separate the two carriers 12 from each other.

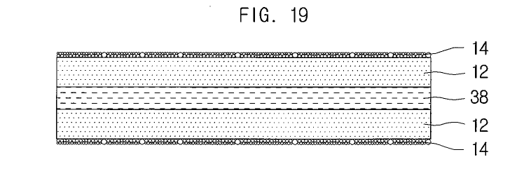

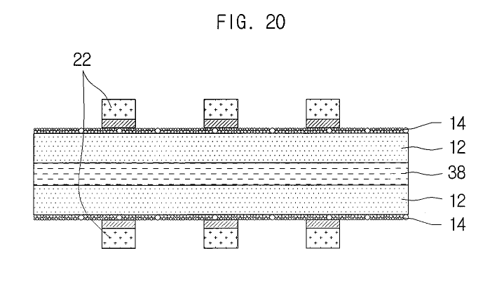

In particular, as shown in FIG. 18 and FIG. 19, each of the two carriers 12 can have one surface on which the thin-film insulating layer 14 is stacked and the other surface which is adhered to one surface and the other surface, respectively, of the foam adhesive layer 38. Roughness can be formed on the thin-film insulating layer 14 by performing the desmear process for the thin-film insulating layer 14. Then, as shown in FIG. 20, the relievo pattern 22 can be simultaneously formed on each of the thin-film insulating layers 14 of two carriers 12 according to the aforementioned method.

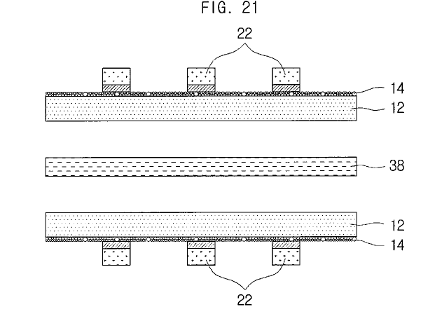

Thereafter, as shown in FIG. 21, if the two carriers 12 formed with the relievo patterns 22 are separated from each other after the adhesive force is weakened by foaming the foam adhesive layer 38, it can be possible to simultaneously obtain the two carriers 12 in which the relievo pattern 22s are formed on the thin-film insulating layers 14.

A printed circuit board can be manufactured according to the aforementioned processes by using the two carriers 12 formed with the relievo patterns 22 obtained by such operations.

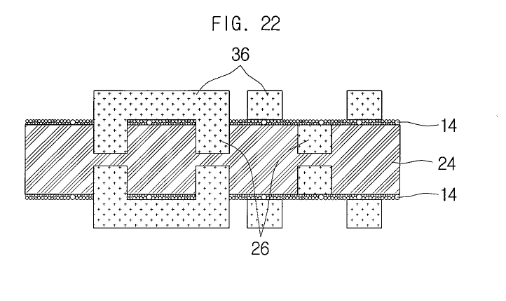

FIG. 22 is a sectional view showing a printed circuit board in accordance with an embodiment of the present invention. In FIG. 22 are shown the thin-film insulating layer 14, the insulator 24, the first circuit pattern 26, and the second circuit pattern 36.

With electronic products trending towards smaller and thinner products, so also is the circuit board undergoing smaller, finer patterns, and higher-density products. The higher-density and finer circuit pattern of the circuit board makes smaller an adjacent distance between circuits (the distance between the center of a circuit and the center of an adjacent circuit is referred to as “pitch”). Accordingly, there may be an insulating defect between circuits or an electric leakage of a circuit, caused by ion-migration, for example.

Accordingly, it may be required to maintain a minimum pitch between adjacent circuits for preventing the insulating defect or the electric leakage in order to form fine circuit patterns. This may be limited to the formation of fine circuit patterns.

The printed circuit board according to this embodiment of the present invention can provide a circuit board having high-density circuit patterns by forming a double layer circuit patterns, the first circuit pattern 26 buried in the insulator 24 and the second circuit pattern 36 formed on the outer layer, without stacking the insulator 24 for forming the multi-layered printed circuit board.

The present invention can also provide a circuit board that can form high density fine-line circuit patterns by forming the thin-film insulating layer 14 between the first circuit pattern 26 buried in the insulator and the second circuit pattern 36 formed on the outer layer and insulating the first circuit pattern 26 and the second circuit pattern 36, to reduce the pitch between adjacent circuits.

In particular, the circuit board according to this embodiment of the present invention, which has essential elements such as the insulator 24, the first circuit pattern 26 being buried in the one surface of the insulator 24, and the second circuit pattern 36 being formed on the thin-film insulating layer 14, can form high density fine-line circuit patterns by forming the thin-film insulating layer 14 between the first circuit pattern 26 buried in the insulator 24 and the second circuit pattern 36 formed on the outer layer to reduce the pitch between adjacent circuits.

The first circuit pattern 26 buried in the insulator 24 can have its broad contact area, thereby improving the bond strength. This can prevent the first circuit pattern 26 from being peeled off. To bury the first circuit pattern 26 in the insulator 24, as described above, a relievo pattern corresponding to the first circuit pattern 26 formed on the thin-film insulating layer 14 can be stacked on and compressed with the insulator 24, thereby allowing the relievo pattern to be compressed in the insulator 24. Then, the relievo pattern can be transcribed in the insulator 24 by removing the carrier 12.

The thin-film insulating layer 14 can prevent a short of the first circuit pattern 26 and the second circuit pattern 36. In this present invention, the thin-film insulating layer 14 can be an insulating layer having a thickness that is thinner than that of the insulator 24 stacked to manufacture a multi-layered printed circuit board.

Roughness can be formed on the thin-film insulating layer 14 by the desmear process. The desmear process can be typically performed to remove a smear remaining on an inner wall of a via hole when the via hole of a board is processed. In this embodiment of the present invention, however, roughness can be formed on the thin-film insulating layer 14 by stacking an epoxy resin or a polyamide imide having a polymer, capable of the chemical roughing, as the thin-film insulating layer 14 on the carrier 12 and performing the desmear process.

A part of the second circuit pattern 36 can be formed so as to overlap with a part of the first circuit pattern 26 by removing a part of the thin-film insulating layer 14 to expose a part of the first circuit pattern 26. The electric connection between the first circuit pattern 26 and the second circuit 36 can be made by removing a part of the thin-film insulating layer 14 to expose a part of the first circuit pattern 26 and then by forming the second circuit pattern 36 on the thin-film insulating layer 14 such that a part of the first circuit pattern 26 overlaps with a part of the second circuit pattern 36.

Hitherto, although some embodiments of the present invention have been shown and described for the above-described objects, it will be appreciated by any person of ordinary skill in the art that a large number of modifications, permutations and additions are possible within the principles and spirit of the invention, the scope of which shall be defined by the appended claims and their equivalents.

What is claimed is:

1. A method for manufacturing a printed circuit board, the method comprising:
forming a relievo pattern corresponding to a first circuit pattern on a thin-film insulating layer stacked on a carrier;
stacking and compressing the carrier with an insulator such that one surface of the carrier on which the relievo pattern is formed faces the insulator;
transcribing the thin-film insulating layer and the relievo pattern in the insulator by removing the carrier;
exposing a part of the relievo pattern by opening a part of the thin-film insulating layer; and
forming a second circuit pattern by selectively depositing a conductive metal on the thin-film insulating layer.

2. The method of claim 1, wherein roughness is formed on the thin-film insulating layer by a desmear process.

3. The method of claim 2, further comprising, prior to the forming of the relievo pattern, desmearing the thin-film insulating layer of the carrier.

4. The method of claim 1, wherein the forming of the relievo pattern comprises:
forming a seed layer on the thin-film insulating layer;
forming a plating resist on the seed layer to correspond to the relievo pattern;
performing electroplating by using the seed layer as an electrode;
peeling off the plating resist; and
removing the exposed seed layer.

5. The method of claim 1, wherein the forming of the second circuit pattern comprises:
forming a seed layer on the thin-film insulating layer;
forming a plating resist on the seed layer to correspond to the second circuit pattern;
performing electroplating by using the seed layer as an electrode;
peeling off the plating resist; and
removing the exposed seed layer.

6. The method of claim 1, wherein the carrier is a metal plate, and the transcribing is performed by etching the metal plate.

7. The method of claim 1, wherein:
the forming of the relievo pattern comprises forming a relievo pattern on each of the thin-film insulating layers of two carriers;
the compressing comprises stacking and compressing the two carriers with the insulator such that one surface of each of the two carriers, on which the relievo pattern is formed, faces either surface of the insulator; and
the transcribing comprises removing the two carriers.

8. The method of claim 7, wherein the forming of the relievo pattern on each of the thin-film insulating layers comprises:
forming a relievo pattern on the thin-film insulating layer of each of the two carriers, of which the other surface is adhered to either surface of a foam adhesive layer; and
separating the two carriers from each other by foaming the foam adhesive layer.

9. The method of claim 1, wherein the forming of the relievo pattern is performed by forming a conductive layer on the thin-film insulating layer and selectively removing the conductive layer.

10. A printed circuit board comprising:
an insulator;
a first circuit pattern being buried on one surface of the insulator;
a thin-film insulating layer being formed on one surface of the insulator; and
a second circuit pattern being formed on the thin-film insulating layer.

11. The printed circuit board of claim 10, wherein roughness is formed on the thin-film layer by a desmear process.

12. The printed circuit board of claim 10, wherein a part of the second circuit pattern is formed to overlap with a part of the first circuit pattern by removing a part of the thin-film insulating layer to expose a part of the first circuit pattern.
